(19) United States
(12) Patent Application Publication
(10) Pub. No.: US 2007/0069612 A1
(43) Pub. Date: Mar. 29, 2007

(54) Piezoelectric resonator and adjustment method

(75) Inventor: Kenji Sato, Hino (JP)

Correspondence Address: HARNESS, DICKEY & PIERCE, P.L.C., P.O. BOX 828, BLOOMFIELD HILLS, MI, 48303, US

(73) Assignee: EPSON TOYOCOM CORPORATION, Tokyo (JP)

(21) Appl. No.: 11/468,176

(22) Filed: Aug. 29, 2006

(30) Foreign Application Priority Data
Aug. 30, 2005 (JP) 2005-249707

(51) Int. Cl. H03H 9/17

(52) U.S. Cl. 310/370

(57) ABSTRACT

A piezoelectric resonator having arms and excitation electrodes that generate flexural vibration in the arms. The piezoelectric resonator includes conductive paste containing metal particles dispersed on the surface of the arms as an additional mass.

### FIELD

The present invention relates to a piezoelectric resonator of a piezoelectric vibratory gyro-sensor using the Coriolis force.

### BACKGROUND

Gyro-sensors are well known as sensors for detecting the rotation, that is, the angular velocity, of objects. The gyro-sensors are capable of detecting the angular velocity without being influenced by the distance between the attachment position and the center of rotation and are used in a wide variety of applications. In recent years, as piezoelectric vibratory gyro-sensors using piezoelectric resonators, crystal resonators in particular, are becoming smaller, more highly precise, and more apt for surface mounting, they are more widely applied in various fields.

FIG. 2 illustrates the external view of a conventional piezoelectric vibratory gyro-sensor as disclosed in JP-A-2004-101392. The horizontal plane (attachment plane) is parallel to the plane of the page of FIG. 2.

The crystal resonator shown in FIG. 2 is formed by wet-etching a thin Z-plate crystal section, a section cut so that the normal of the primary substrate plane is oriented along the Z axis of the crystal, in the shape of a dual tuning fork, with a predetermined electrode formed on the surface thereof by vapor deposition or sputtering, and is equipped with: excitation sections 3 including a pair of prong-shaped arms 1a, 2b and excitation electrodes 2a, 2b formed on the surfaces of the arms 1a, 1b; dual tuning fork support sections 4, 5 supporting both ends of the excitation sections 3 and including lead electrodes each connected to the excitation electrodes 1a, 1b; a detection section 7 including detection electrodes 6a, 6b and detecting vibrations of the arms 1a, 1b by way of the dual tuning fork support section 4; a detection section 9 including detection electrodes 8a, 8b and detecting vibrations of the arms 1a, 1b by way of the dual tuning fork support section 5; a support securing section 11 supporting one end of the detection section 7 and including a pair of lead-out electrodes 10a, 10b connected respectively to the detection electrodes 6a, 6b; and a support securing section 13 supporting one end of the detection section 9 and including lead-out electrodes 12a, 2b connected respectively to the detection electrodes 8a, 8b. The back side is also formed with the same electrode patterns for the excitation electrodes, the detection electrodes, the lead-out electrodes, and the lead electrodes shown in FIG. 2 and is connected by way of patterns on the side surface.

Further, the support securing section is secured by adhesives on the attachment plane (horizontal plane) of the package or the like of the crystal resonator, but this is not shown in the drawing.

The described piezoelectric vibratory gyro-sensor (the crystal resonator) operates as below.

First, as shown in FIG. 3A, when an excitation signal is sent to the excitation electrodes 1a, 1b in a non-rotating state, the arms 1a, 1b experience a flexural vibration (excitation mode) referred to as an in-plane symmetrical first flexural vibration mode. In this case, the arms 11a and 11b vibrate symmetrically on the left and right in the drawing. As the vibratory gyro-sensor is vibrating in this excitation mode, an angular velocity (rotation) around the crystal Z axis is applied. When this happens, the Coriolis force acts on the arms 1a, 1b with the force acting on one arm in the Y direction (upward in the drawing) and on the other arm in the Y direction (downward in the drawing). As a result, the opposite Coriolis forces to the left and right generate a flexural vibration referred to as an in-plane asymmetrical second flexural mode (detection mode) in the arms 1a, 1b as shown in FIG. 3B, and this flexural vibration is detected by the detection sections 7, 9.

It is ideal if no signal is output from the detection sections (detection electrodes) in the excitation mode. However, in reality, the arms become slightly off-balance due to such reasons as manufacturing variations, and it is known that unwanted signal is output from the detection sections in the excitation mode (non-rotating state). This is referred to as leak output, and it negatively affects not only the detection part but also a Q value of the excitation mode. For example, if the leak output increases, excitation vibration energy leaks, resulting in decrease in the Q value, increase in an equivalent resistance, or increase in electric consumption. Further, the decrease in the Q value causes decrease in detection sensitivity and increase in noise. Moreover, the piezoelectric vibratory gyro-sensor becomes readily affected by external vibrations, which negatively affect various characteristics of the gyro-sensor.

Therefore, in order to minimize this leak output, adjustment is independently made on the crystal resonator. Generally, for example, metal film is formed for adjustment in advance on part of the arms, and part the metal film is then trimmed by laser or ions. Also, it is possible to trim part of the excitation electrodes. In this case, it is desirable to thicken the film and to increase the adjustment amount. The metal film is generally formed by sputtering, vacuum deposition, or plating. However, it is difficult to thickly form the metal film by sputtering or vacuum deposition. Thus, conventionally, the metal film is formed by plating in a desired thickness.

Patent Document 1: JP-A-2004-101392

However, formation of the metal film through plating requires a large quantity of chemicals for masking the non-plated part and for treatments thereafter and requires a number of facilities and processes. Therefore, it is a problem that the adjustment cost increases, making it extremely difficult to reduce costs.

### SUMMARY

The object of the present invention is to overcome the problems as described above and to provide a piezoelectric resonator of a piezoelectric vibratory gyro-sensor and an adjustment method at reduced cost for the adjustment.

In order to achieve these objects, the present invention relates to a piezoelectric resonator having arms and excitation electrodes that generate flexural vibration in the arms, the piezoelectric resonator including conductive paste containing metal particles dispersed on the surface of the arms as an additional mass.

Further, the present invention relates to a method for adjusting a piezoelectric resonator having arms and excitation electrodes that generate flexural vibration in the arms, the method including: ejecting from a nozzle of an inkjet printer a predetermined amount of conductive paste containing dispersed metal particles, applying this to a predetermined position of the arms, and sintering this at a predetermined temperature so as to achieve desired vibration characteristics using the conductive paste as an additional mass.

The present invention further relates to the method for adjusting the piezoelectric resonator, further including trimming part of the conductive paste by laser or ions after sintering the conductive paste at a predetermined temperature so as to achieve desired vibration characteristics.

The present invention aims to achieve the desired vibration characteristics by ejecting conductive paste containing dispersed metal particles from a nozzle of an inkjet printer, applying this to a predetermined position of the surface of the arms of a tuning fork type piezoelectric resonator, and sintering this at a predetermined temperature. As a consequence, it becomes possible to use the conductive paste of metal nano particles as the additional mass for adjustment and to provide a high precision tuning fork type piezoelectric resonator at reduced cost for the adjustment.

### BRIEF DESCRIPTION OF THE DRAWINGS

FIGS. 1A and 1B illustrate the external view of a dual tuning fork type crystal resonator and an adjustment method according to the present invention;

FIG. 2 illustrates an external view of the dual tuning fork type crystal resonator and the composition of electrodes; and

FIGS. 3A and 3B illustrate excitation states of the dual tuning fork type crystal resonator.

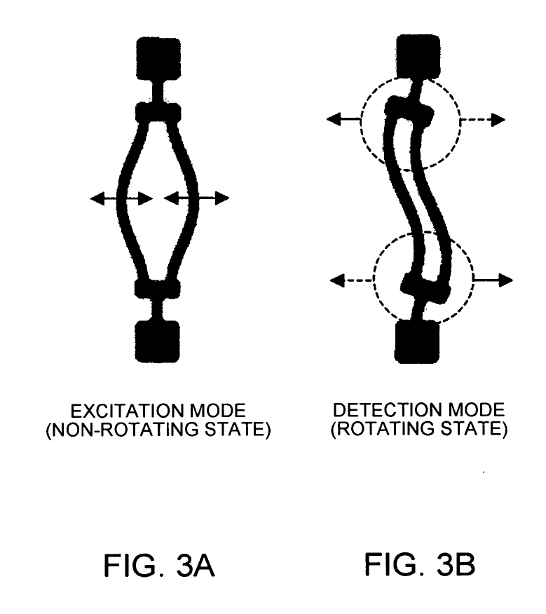

### DETAILED DESCRIPTION

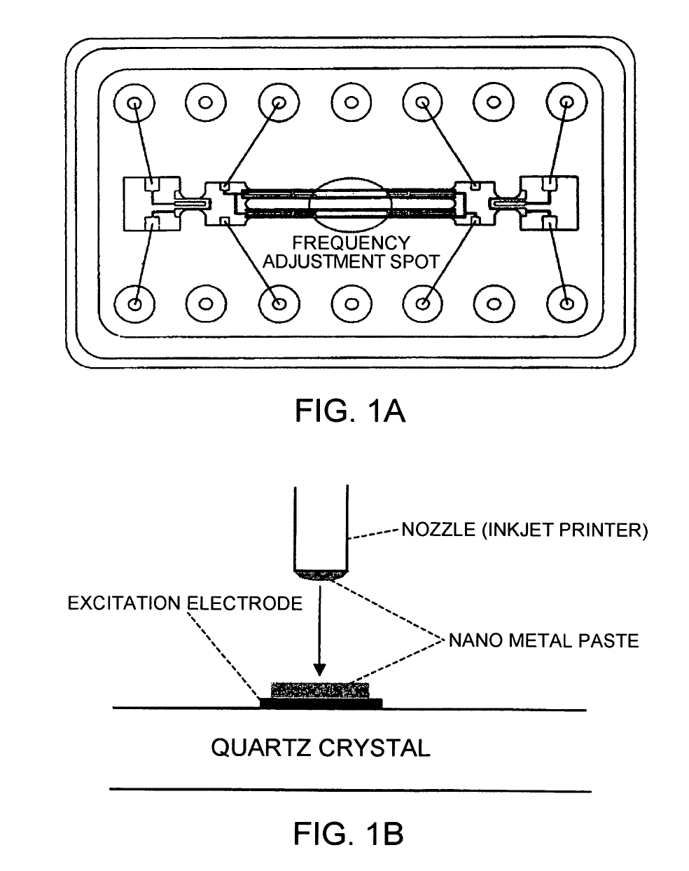

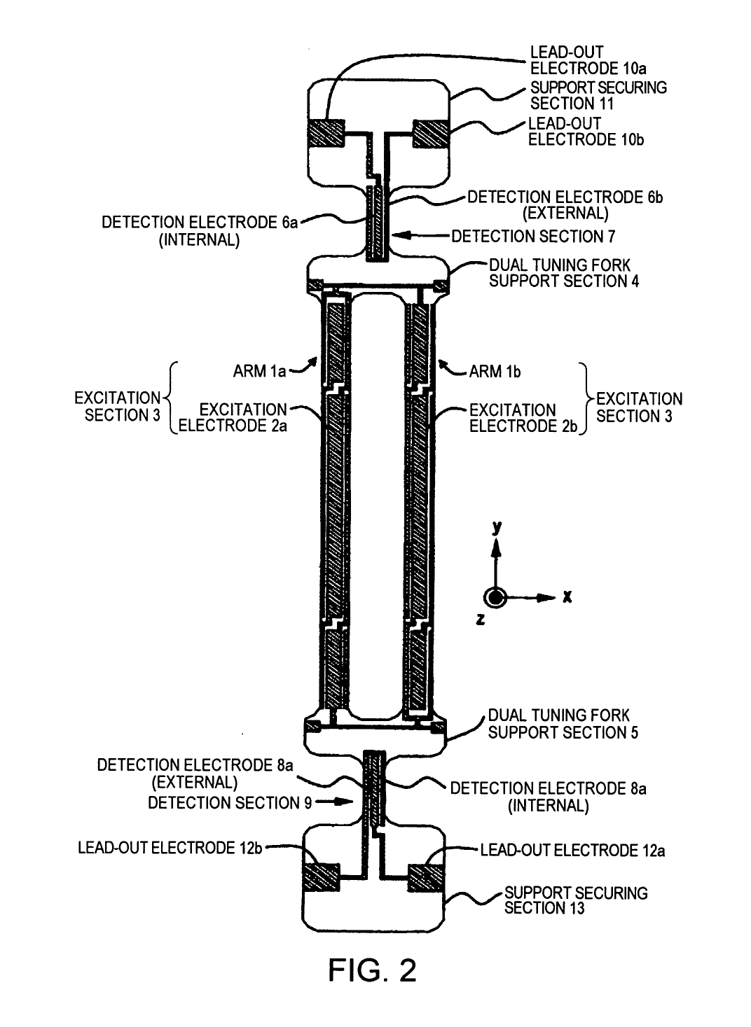

In the following, the present invention will be described in detail based on the embodiments shown in the drawings. FIG. 1A shows a state in which the dual tuning fork crystal resonator of the present invention is packaged. In FIG. 1A, the structure of the dual tuning fork crystal resonator is identical to the one shown in FIG. 2 and will not be described in detail. The most characteristic part of the present invention is that a frequency adjustment spot is provided on the surface at the center of the arms (on the excitation electrodes), to which the conductive paste of metal nano particles (referred here as nano metal paste) is applied as the additional mass so that the leak output from the detection electrodes (not shown) is reduced.

The nano metal paste will now be described. The nano metal paste is a conductive paste mainly consisting metal microparticles of several nanometers. It was developed as a material to directly plot ultra-fine wire of several micron order on a print substrate. In general, the metal nano particles having high surface activity tend to melt together at room temperature, forming several ten to several hundred aggregates. However, stably dispersed nanoparticles whose surfaces are covered with a specific dispersant do not aggregate and can stay stable in an organic solvent.

Recently, Harima Chemicals, Inc. has developed a paste composition (trade name: Nano Paste) of stably dispersed metal nano particles (gold or silver) evenly dispersed in a thermo-setting resin, and the composition has drawn attention.

The method for adjusting the dual tuning fork crystal resonator of the present invention will now be described.

FIG. 1B shows a method for applying the nano metal paste to the frequency adjustment spot of the dual tuning form crystal resonator. As shown in FIG. 1B, the nano metal paste is ejected from a nozzle by employing the same principle as that of a commercially available inkjet printer and is applied to the frequency adjustment spot. The minimum amount of dots ejected from the commercially available inkjet printer is about a few pico liters (equivalent to a sphere volume of about 20 microns in diameter). Accordingly, this can be the minimum unit for one application.

While monitoring the leak output from the two detection electrodes (not shown), the application amount and position are adjusted so as to minimize the leak output. If the metal particles of the nano metal paste are gold (Au), a sintering phenomenon that normally takes place at 800° C. or more is known to take place at about 250° C.

Therefore, after the nano metal paste is applied, the entire dual tuning fork crystal resonator is placed in a reflow bath or a high-temperature furnace for drying so that the applied nano metal paste can be readily sintered at the relatively low temperature. Also, since the additional mass can be added at the predetermined position and amount, high precision adjustment is possible. Further, since it is not necessary to conduct a resist treatment for protection film used in the conventional plating or to use a large quantity of chemicals, the adjustment process can be environmentally friendly. There is a case in which the characteristics of the crystal resonator slightly change upon sintering of the nano metal paste. In this case, part of the sintered nano metal paste may be trimmed by laser, ions, or the like so that the characteristics can be re-adjusted.

The adjustment method just described is for the purpose of minimizing the leak output from the detection electrodes. However, the present invention is not limited to this purpose but can be used, for example, for the purpose of adjusting a detuning frequency of the piezoelectric resonator.

As described, when the excitation signal is sent to the excitation electrodes in a non rotating state of the piezoelectric vibratory gyro sensor, the dual tuning fork experiences the excitation vibration at a given amplitude. When the frequency of the excitation signal is varied in this situation, there exists a frequency (a resonance frequency at the excitation mode) at which the amplitude of the excitation vibration is maximized. In contrast, in a rotating state of the piezoelectric vibratory gyro sensor in this situation, the flexural vibration referred to as the in-plane asymmetrical second flexural mode (the detection mode) occurs as described earlier. In this case, when the frequency of the excitation signal is varied, there exists a frequency (a resonance frequency at the detection mode) at which the amplitude of the flexural vibration is maximized.

The difference between these two resonance frequencies is referred to as the detuning frequency. It is known that, when the detuning frequency is low, the detection sensitivity increases, and when the detuning frequency is high, the detection sensitivity decreases. Therefore, by using the adjustment method of the invention, it is possible to adjust the detuning frequencies in order to obtain suitable detection sensitivity.

Additionally, if the electrodes are composed in a manner that the part for adjusting the resonance frequency in the excitation mode differs from the part for adjusting the resonance frequency in the detection mode, such as the electrode composition shown in the present embodiment, the two resonance frequencies can be adjusted substantially independently, and, thus, such an electrode composition is highly usable.

Moreover, the present adjustment method is applicable not only to the dual tuning fork type piezoelectric resonators but also to single tuning fork type piezoelectric resonators. Certainly, the adjustment method is not limited to the tuning fork type piezoelectric resonators but is also capable of adjusting characteristics of any type of resonators, as long as they are of a type that generates the flexural vibration.

As described hereinbefore, according to the present invention, the nano metal paste is applied to the tuning fork type piezoelectric resonator and sintered at about 250° C. by employing the same principle as that of the commercially available inkjet printer, and the obtained product is utilized as the additional mass for the adjustment. Therefore, it is possible to provide a high precision tuning fork type piezoelectric resonator at reduced cost for the adjustment.

The entire disclosure of Japanese Patent Application No. 2005-249707, filed Aug. 30, 2005 is expressly incorporated by reference herein.

1. A piezoelectric resonator having arms and excitation electrodes that generate flexural vibration in the arms, the piezoelectric resonator comprising a conductive paste containing metal particles dispersed on the surface of the arms as an additional mass.

2. A method for adjusting a piezoelectric resonator having arms and excitation electrodes that generate flexural vibration in the arms, the method comprising:
ejecting from a nozzle of an inkjet printer a predetermined amount of conductive paste containing dispersed metal particles, applying said paste to a predetermined position of the arms, and sintering said paste at a predetermined temperature so as to achieve desired vibration characteristics using said conductive paste as an additional mass.

3. The method for adjusting the piezoelectric resonator according to claim 2, further comprising trimming part of said conductive paste by laser or ions after sintering said conductive paste at a predetermined temperature so as to achieve desired vibration characteristics.
